(19) United States
(12) Patent Application Publication
(10) Pub. No.: US 2014/0217492 A1
(43) Pub. Date: Aug. 7, 2014

(54) CHARGE-TRAP TYPE FLASH MEMORY DEVICE HAVING LOW-HIGH-LOW ENERGY BAND STRUCTURE AS TRAPPING LAYER

(71) Applicant: NATIONAL TSING HUA UNIVERSITY, Hsinchu City (TW)

(72) Inventors: Kuei-Shu Chang-Liao, Hsinchu City (TW); Zong-Hao Ye, Hsinchu City (TW)

(73) Assignee: NATIONAL TSING HUA UNIVERSITY, Hsinchu City (TW)

(21) Appl. No.: 13/758,713

(22) Filed: Feb. 4, 2013

(51) Int. Cl. H01L 29/792

(52) U.S. Cl. CPC H01L 29/792
USPC 257/324

(57) ABSTRACT

A charge-trap type flash memory device having a low-high-low energy band as a trapping layer embeds Al₂O₃ between Si₃N₄ and HfO₂ as a CT layer. Most injected charged can be trapped at an interface of Si₃N₄/Al₂O₃. Al₂O₃ can also provide a high blocking effect for electronic dissipation. Therefore this invention can enhance the writing and retention characteristics for CT VNM.

### BACKGROUND OF THE INVENTION

1. Field of the Invention

The present invention relates to provide a charge-trap type flash memory device, and particularly to a charge-trap type flash memory device in which trapped charges can be regulated by embedding Al₂O₃ to the interface of Si₃N₄/HfO₂ to further enhance the writing and trapping characteristics of the T NVM device

2. Description of Related Art

A Nonvolatile Memory (NVM) device trapping charges in a trapping layer of high dielectric material has been often discussed. The writing performance of such a device can increase with the use of the charge trapping layer of high dielectric material, because it has greater trapping density and smaller conduction band offset than silicon. However, the high dielectric material has trapping problem due to its lower crystallization temperature and shallow trap level. Therefore, a stacked charge trapping (Charge Trapping, CT) layer made of silicon nitride (Si₃N₄)/high dielectric material is proposed to improve the trapping characteristics. Deeper trap level and higher crystallization temperature of Si₃N₄ provide an effective barrier to effectively block those charges trapped in the high-k material such as hafnium oxide (HfO₂). Si₃N₄ have smaller valence band offset which help to realize higher erasing speed. Furthermore, it is reported that embedding (Al₂O₃) to Si₃N₄ (i.e., Si₃N₄/Al₂O₃/Si₃N₄ trapping layer) can help regulate the distribution of the trapped charges to obtain the characteristics of a multi-stage memory. The trapping layer is a Si3N4-based one which limits the size scaling of the device. Si₃N₄/Al₂O₃/high-k material as a stacked CT layer for CT NVM device has been proposed and researched about the double-layered stacked structure on Si3N4 with various high-k films. As shown in FIG. 5, specimens S2 and S3 represent the double-layered stacked CT layer, in which the specimen S2 has a stacked Si₃N₄/HfO₂ as the CT layer, and the specimen S3 has stacked silicon nitride/alumina hafnium (Si₃N₄/HfAlO) as CT layer. The specimen S1 having a single-layered HfAlO (1:1) high-k CT layer is taken as a control sample.

FIG. 6A is a schematic view of comparison of writing/erasing characteristics of conventional specimens S1, S2 and S3. FIG. 6B is a schematic view of comparison of retention characteristics of conventional specimens S1, S2 and S3. As shown, the results of operating characteristics of the specimens S1, S2 and S3 at V_{Program} (V_{P}) [=V_{Gate} (V_{G})−V_{Flatband} (V_{FB})]=14V and V_{Erase} (V_{E}) [=(V_{Gate} (V_{G})−V_{Flatband} (V_{FB})]=−14V show that the specimens S2 an S3 having stacked CT layers has higher writing and erasing speeds than the specimen S1 having single-layered S1. The reason can be attributed that the device having Si3N4 as the first CT layer has smaller conduction band and valence band energy level difference. In addition, the specimen S2 having Si₃N₄/HfO₂ stacked CT layer reveals higher writing speed than the specimen S3 having Si₃N₄/HfAlO stacked CT layer. HfO₂ has higher trapping density and smaller conduction band offset compared to HfAlO. On the other hand, the specimen S3 shows higher erasing speed than the specimen S2 because more electrons are trapped in Si₃N₄ after the writing operation. This part of electrons highly intend to dissipate furthermore, because the potential well formed by Si₃N₄/HfAlO/Al₂O₃ is more shallow than Si₃N₄/HfO₂/Al₂O₃, the electrons trapped in HfAlO are more easily to lose than those trapped in HfO₂. The retention characteristics for the specimens S1, S2, and S3 are shown in FIG. 6 B. The sample with Si₃N₄/HfO₂ stacked CT layer (S2) is the best; this can be attributed to the deeper trap level for Si₃N₄, compared to HfAlO. Moreover, the charge loss in HfO₂ for sample S2 can be suppressed due to the deeper potential well of HfO₂ between the Si₃N₄ and Al₂O₃ blocking layer shown as (2), (3), (5), and (6) in the inset of FIG. 6 B. The specimen S2 having Si₃N₄/HfO₂ stacked CT layer is superior in terms of electricity and the durability.

The inventors use double-layered Si₃N₄/HfO₂ as the CT layer and embed HfxAl₁₋ₓO between Si₃N₄ and HfO₂ to form a three-layered CT layer for comparison. The result shows that the structure using three-layered Si₃N₄/HfxAl₁₋ₓO/HfO₂ stacked Layer as the CT layer has no significant improved performance, compared to the structure having the double-layered Si₃N₄/HfO₂ layer as the CT layer. Therefore those conventional devices are unable to meet the requirements of the current CT NVM device. Therefore, they cannot meet the needs for the users in actual use.

### SUMMARY OF THE INVENTION

A main purpose of this invention is to provide a charge-trap type flash memory device having a low-high-low energy band structure as a trapping layer, which can effectively improve the shortcomings of prior art. Embedding Al₂O₃ to the interface of Si₃N₄/HfO₂ can further improve the writing speed and trapping characteristics of the CT NVM device. More charges can be trapped in a charge trapping layer of Si3N4 layer in 10⁻⁵ seconds by regulating the location of charges. Thereby, the writing and trapping characteristics of a CT NVM can be enhanced.

Another purpose of the invention is to provide a charge-trap type flash memory device which has short operating time, low voltage, long life cycle, and high number of cycles.

In order to achieve the above and other objectives, the charge-trap type flash memory device having a low-high-low energy band as a trapping layer according to the invention includes a silicon substrate, a charge trapping (CT) layer, a tunnel oxide layer, a metal gate electrode, and a blocking oxide layer.

The charge trapping layer is used to trap charges. The charge trapping layer includes a silicon nitride (Si₃N₄) film, an intermediate oxide layer and a hafnium oxide (HfO₂) film. The silicon nitride film contributes to improve the retention characteristics; the intermediate oxide layer is used to regulate the distribution of the trapped charges. The hafnium oxide film is used to increase the memory window. The conduction band offset (ΔEc) of the intermediate oxide layer is greater than that of the silicon nitride film and the hafnium oxide film.

The tunneling oxide layer is between the silicon substrate and the charge trapping layer to prevent any charges from losing from the charge trapping layer to the silicon substrate.

The blocking oxide layer is between the charge trapping layer and the metal gate electrode to block any charges so as to prevent any loss from the charge trapping layer to the metal gate electrode.

In one embodiment of the invention, the intermediate oxide layer is selected from silicon oxynitride (SiON), aluminum oxynitride (AlON) or aluminum oxide (Al₂O₃).

In one embodiment of the invention, the charge trapping layer is made of high dielectric constant (high-κ) material

In one embodiment of the invention, the tunneling oxide layer has a thickness of 2˜4 nanometers (nm).

In one embodiment of the invention, an equivalent silicon nitride thickness of the charge trapping layer including the silicon nitride film, an intermediate oxide layer and a hafnium oxide is 5˜7 nm.

In one embodiment of the invention, the silicon nitride film has a thickness of >3 nm.

In one embodiment of the invention, the intermediate oxide layer has a thickness of ≦3 nm.

In one embodiment of the invention, the blocking oxide layer has a thickness of 12˜18 nm.

In one embodiment of the invention, the metal gate electrode has a thickness of 40˜60 nm.

In one embodiment of the invention, the metal gate electrode is the one which is patterned by etching.

### BRIEF DESCRIPTION OF THE DRAWINGS

FIG. 1 is a schematic view of a structure and its conduction band offset of a charge-trap type flash memory device having a low-high-low energy band structure as a trapping layer according to the present invention.

FIG. 2 is a schematic view of a three-layered stacked structure of Si₃N₄/various high-k/HfO₂ of a charge-trap type flash memory device according to the invention.

FIG. 3A is a schematic view of comparison in writing/erasing characteristics of specimens S4, S5 and S6 according to the invention.

FIG. 3B is a schematic view of comparison in retention characteristics of specimens S4, S5 and S6 according to the invention.

FIG. 4A is a schematic view showing a curve of trapped charges simulating for a CT NVM memory device having a Si₃N₄/HfO₂ or CT layer of Si₃N₄/Al₂O₃/HfO₂ layer after writing operation according to the invention.

FIG. 4B is a schematic view showing the percentage of V_{fb} shifts at different CT layers and time point according to the present invention.

FIG. 5 is a schematic view of double-layered stacked structure having various high-k films on Si₃N₄ in the prior art.

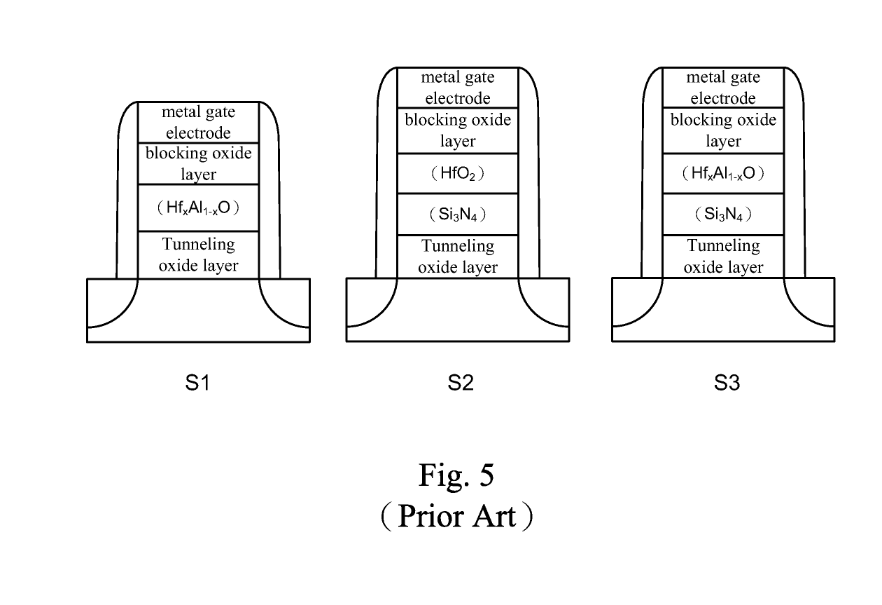

FIG. 6A is a schematic view of comparison of writing/erasing characteristics of conventional specimens S1, S2 and S3.

FIG. 6B is a schematic view of comparison of retention characteristics of conventional specimens S1, S2 and S3.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended tables.

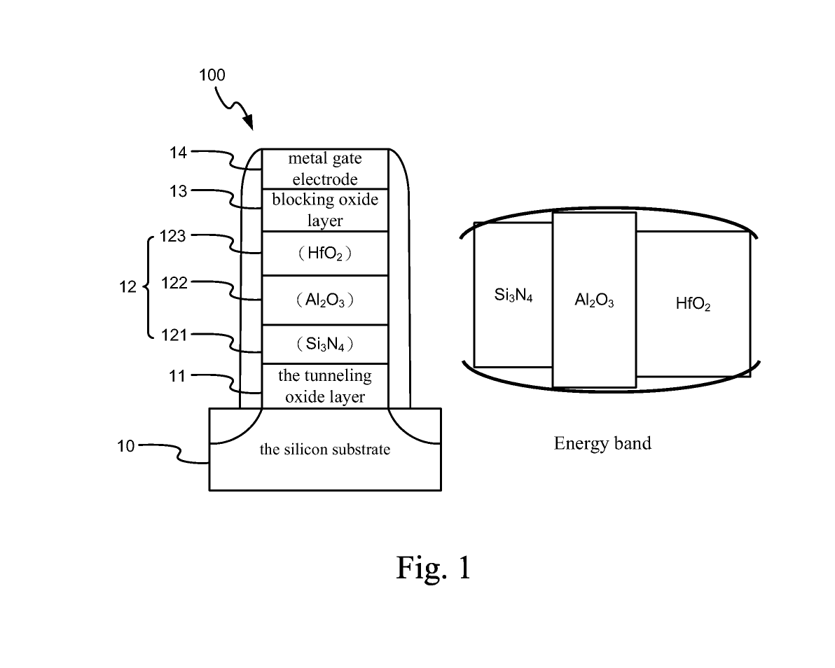

FIG. 1 is a schematic view of a structure and its conduction band offset of a charge-trap type flash memory device having a low-high-low energy band structure as a trapping layer according to the present invention. As shown, the charge-trap type flash memory device 100 according to the invention at least includes a silicon substrate 10, a tunneling oxide layer 11, a charge trapping layer 12, a blocking oxide layer 13, and a metal gate electrode 14

The tunneling oxide layer 11 is formed on the silicon substrate 10, and has a thickness of 2˜4 nanometers (nm) in order to prevent any charges from losing from charge trapping layer 12 to the silicon substrate 10.

The charge trapping layer 12 is formed on the tunneling oxide layer 11 and is made of high dielectric constant (high-κ) material used to store the charges. The charge trapping layer 12 consists of a silicon nitride (Si₃N₄) film 121, an intermediate oxide layer 122 and a hafnium oxide (HfO₂) film 123. The silicon nitride film 121 contributes to improve the retention characteristics. The intermediate oxide layer 122 is used to regulate the distribution of the trapped charges. The hafnium oxide film 123 is used to increase the memory window. The conduction band offset (ΔEc) of the intermediate oxide layer 122 is greater than that of the silicon nitride film 121 and the hafnium oxide film 123.

The blocking oxide layer 13 is formed on the charge trapping layer 12, and has a thickness of 12˜18 nm for blocking any charge lost from the charge trapping layer 12 to the metal gate electrode 14.

The metal gate electrode 14 is formed on the blocking oxide layer 13, and has a thickness of 40˜60 nm.

An equivalent silicon nitride thickness of the charge trapping layer 12 is 5˜7 nm. The silicon nitride film 121 has a thickness of >3 nm. The intermediate oxide layer 122 has a thickness of ≦3 nm, and can be selected from silicon oxynitride (SiON), aluminum oxynitride (AlON) or aluminum oxide (Al₂O₃).

Thereby the above structure constitutes a novel charge-trap type flash memory device having a low-high-low energy band structure as the trapping layer.

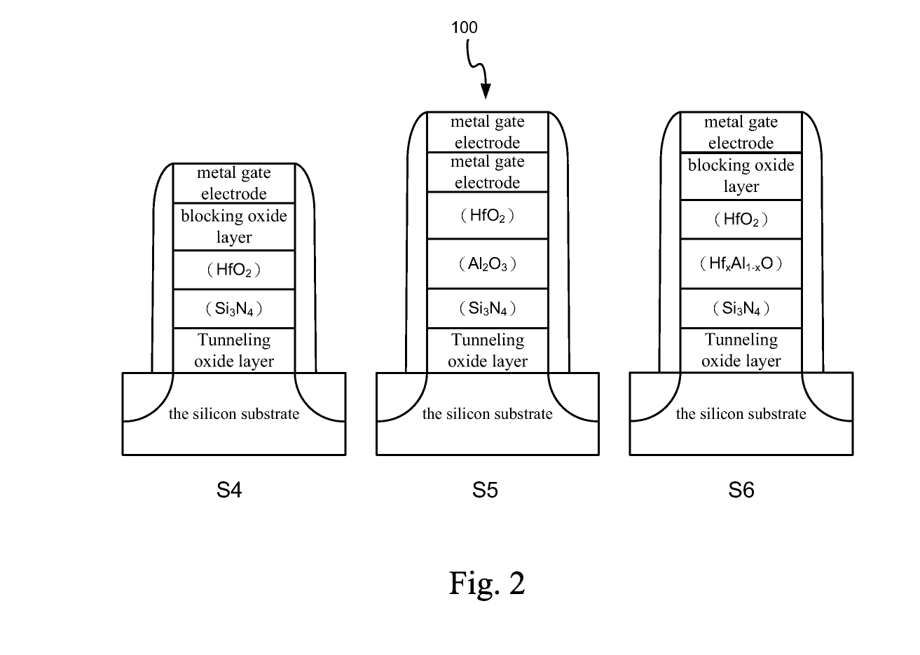

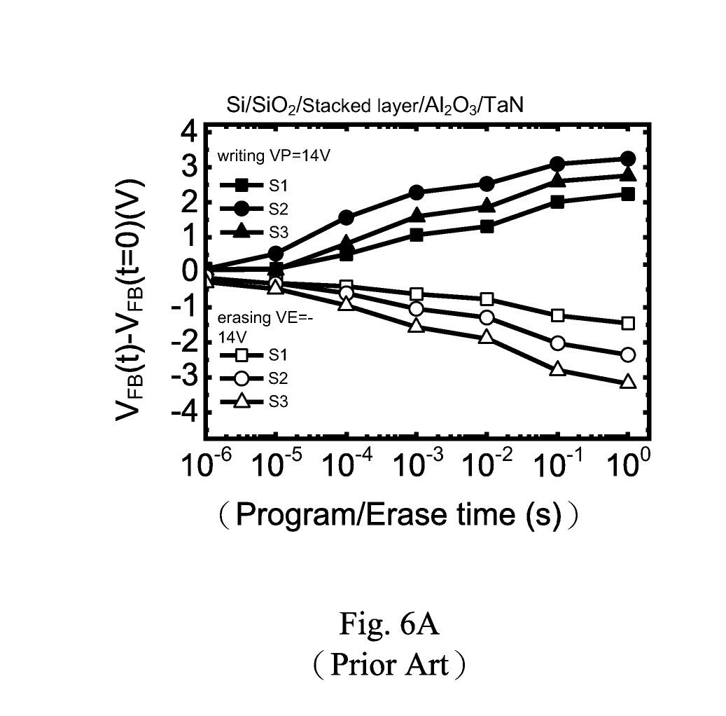

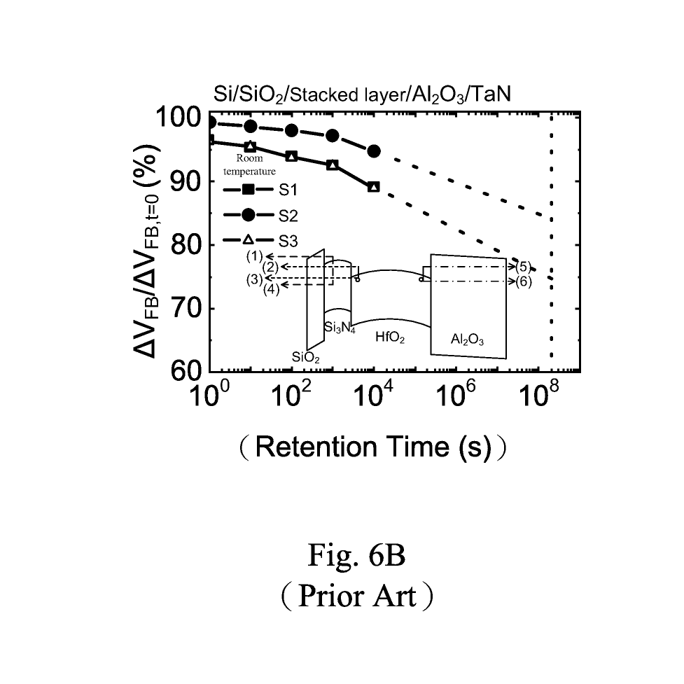

FIG. 2 is a schematic view of a three-layered stacked structure of Si₃N₄/various high-k/HfO₂ of a charge-trap type flash memory device according to the invention. As shown: a CT NVM device 100 according to the present invention, in a specific embodiment, is manufactured on a p-type silicon substrate to form 3 nm-thick silica (SiO₂) first on a silicon substrate as the tunneling oxide layer. Subsequently, six specimens of six different CT layers are made up, as shown in Table I individually. The specimens S1, S2 and S3 are compared in terms of effects of a double CT layered stacked structure (such as shown in FIG. 6A and FIG. 6B). Then, choose three layers having Si₃N₄/various high-k/HfO₂, S4, S5 and S6 are compared in terms of effects of CT layered stacked structure. The specimen S4 having Si₃N₄/HfO₂ as the CT layer is taken as a control sample to compare the specimens S5 and S6 having Al₂O₃ or HfAlO (2:1) embedded between Si₃N₄ and HfO₂ as the CT layer. In the process of preparing the above charge trapping layer 12, a Si₃N₄ film having a thickness greater than 3 nm is formed on the tunneling oxide layer by low pressure chemical vapor deposition (LPCVD). All of the high-dielectric materials are used to in turns deposit an Al₂O₃ layer as the intermediate oxide layer and an HfO₂ film on the Si₃N₄ film by using organic metal chemical vapor deposition (MOCVD). Subsequently, an Al₂O₃ film having a thickness of about 15 nm is deposited as the blocking oxide layer by using MOCVD system. Then a 50 nm-thick TaN is deposited as a metal gate electrode by sputtering. Then all the specimens are subject to rapid, high temperature annealing in a nitrogen atmosphere at 900° C. for 30 seconds. Thereafter, a 300 nm-thick aluminum (Al) film (not shown) is deposited by sputtering, and patterned by etching the metal gate electrode using spiral wave plasma Finally, a sintering process is carried out in a mixed atmosphere of nitrogen/hydrogen (N₂/H₂) at 400° C. for 30 minutes.

TABLE I

| No. | S1 | S2 | S3 | S4 | S5 | S6 |
|---|---|---|---|---|---|---|
| Metal gate electrode | TaN(50 nm) | | | TaN(50 nm) | | |
| Blocking oxide layer | Al₂O₃(15 nm) | | | Al₂O₃(15 nm) | | |
| Various charge trapping | HfAlO | HfO₂ | HfAlO | HfO₂ | HfO₂ | HfO₂ |
| layers | (1:1) | (10 nm) | (1:1) | (14 nm) | (7.5 nm) | (7.5 nm) |
| | (15 nm) | | (7.5 nm) | | Al₂O₃ | HfAlO |
| | | | | | (3 nm) | (2:1) |
| | | | | | | (6.5 nm) |

| | |
|---|---|
| Si₃N₄(3 nm) | Si₃N₄(3 nm) |

| | | |
|---|---|---|
| Tunneling oxide layer | SiO₂(3 nm) | SiO₂(3 nm) |
| substrate | P type substrate | P type substrate |

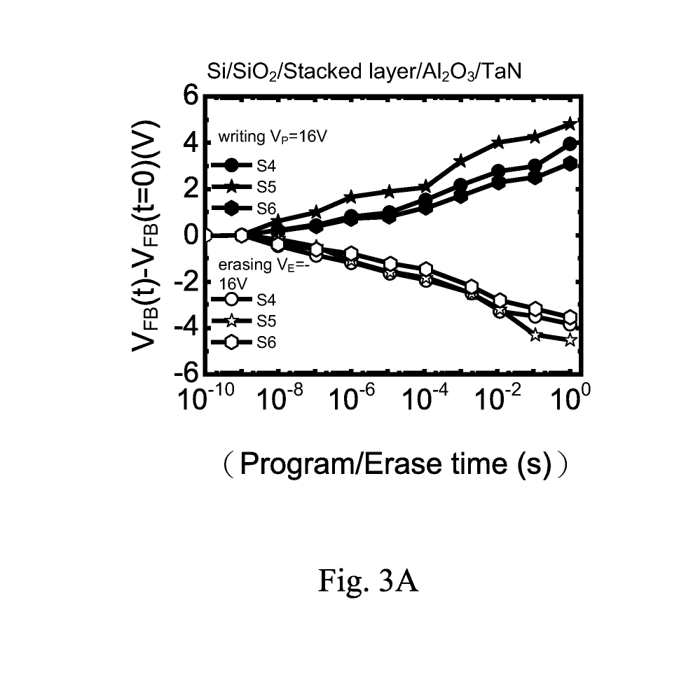

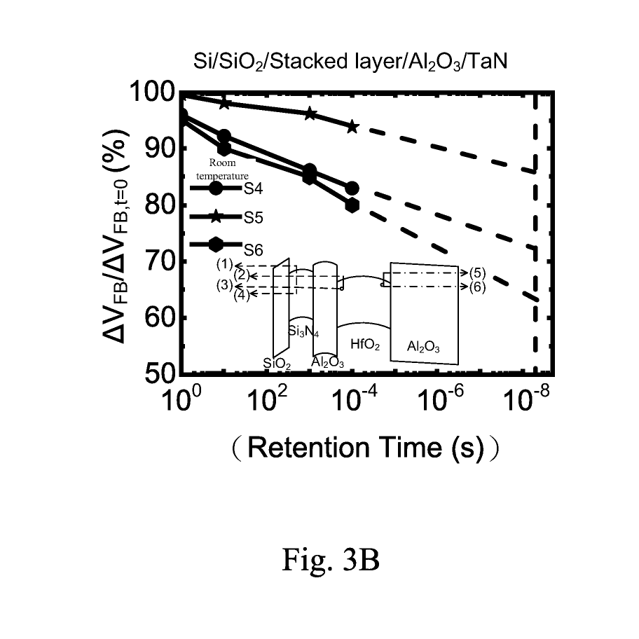

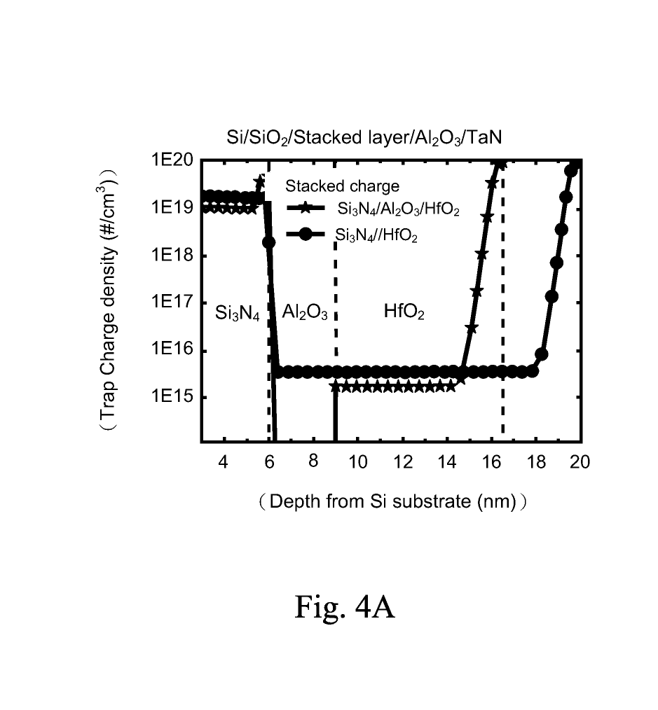

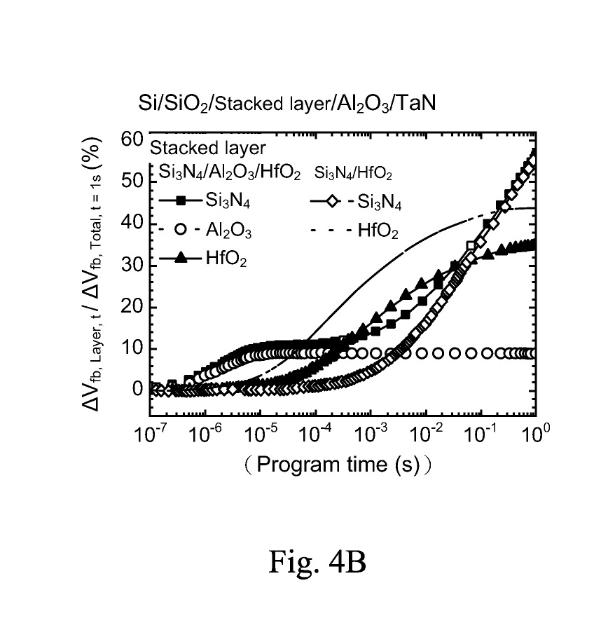

FIG. 3A shows the W/E characteristics at V_{Program} (V_{P}) [=V_{Gate} (V_{G})−V_{Flatband} (V_{FB})]=16 V and V_{Erase} (V_{E}) [=V_{Gate} (V_{G})−V_{Flatband} (V_{FB})]=−16 V for the S4, S5, and S6 samples. It can be seen that the sample with Si₃N₄/Al₂O₃/HfO₂ CT layer (S5) has the fastest programming speed since it can modulate the trapped charge distribution. It is believed that electrons trapped at the CT/blocking layer interface increase the leakage current from the CT layer to the metal gate during writing operation. By inserting an Al₂O₃ layer between Si₃N₄ and HfO₂, most of the injected electrons are trapped at the Si₃N₄/Al₂O₃ interface and thus lower the leakage current. In addition, the programming speed of the sample with inserting an HfAlO (1:1) layer between Si₃N₄ and HfO₂ (S6) is slower than that with Si₃N₄/HfO₂ double layers (S4). It is due to the larger trap density of HfO₂ than that of HfAlO. The erase speeds are similar for all samples. This is because the valence band offset of their second trapping layer (HfO₂, Al₂O₃, and HfAlO for samples S4, S5, and S6, respectively) is larger than that of the first one (Si₃N₄). Retention characteristics for the S4, S5, and S6 samples are shown in FIG. 3B. The sample with Si₃N₄/Al₂O₃/HfO₂ trapping layer (S5) performs best because there is an additional barrier provided by Al₂O₃ to suppress the detrapping of electrons in HfO₂. Moreover, the number of charges trapped into Si₃N₄ bulk for sample S5 is smaller, compared with sample S4 [see FIG. 4A]. The aforementioned explanations are depicted by (1), (2), (3), and (4) shown in the inset of FIG. 3B; they result in less charge detrapping during the retention test.

FIG. 4A shows the simulated trap charge profiles for CT NVM memory devices with Si₃N₄/HfO₂ or Si₃N₄/Al₂O₃/HfO₂ CT layer, i.e., samples S4 or S5, after writing operation (Vg=16 V, 1 s). It is obvious that a trapped-charge peak density is located at the Si₃N₄/Al₂O₃ interface for sample S5; this agrees with the aforementioned explanations. FIG. 4B shows the simulated percentages of the V_{fb} shifts in the different CT layers with time. The V_{fb} shifts can be obtained via the following equation:

ΔV_{fb}=qN_{avg}t_{Layer}/C_{Layer};

wherein q is the electronic charge; Navg is the CT layer of average trapped charge density; t_{Layer} is the physical thickness of each CT layer; and C_{Layer} is capacitance per unit area as seen in the direction of the gate within each CT layer. The average trapped charge density (N_{avg}) of the CT layer can be estimated by the following equation:

N_{avg}=∫₀^{t}^{_{Layer}}n(y)dy/t_{Layer},

wherein y is the direction of stacking the trapping layer; and n (y) is the density of the trapped charges along the direction of the stacked trapping layer.

It is clear that the percentages of the V_{fb} shifts in Si₃N₄ before a writing time of 10⁻⁵ s the for the S5 sample are more than those for the S4 one. This is because an additional electron barrier is provided by Al₂O₃, and it can decrease the chance for electrons for tunneling to the third CT layer. Obviously, from the percentage of the V_{fb} displacement, it is known that the performance of the writing speed of the specimen S5 is far better than the other specimens (such as S4), which means more charges can be trapped in the Si₃N₄ layer in 10⁻⁵ seconds. This is because Al₂O₃ provides one additional electron blocking energy barrier which can reduce the probability of electrons penetrating the third CT layer.

According to the study of operational characteristics of CT NVM devices respectively having single-layered, double-layered and three-layered trapping layers, it is found that the CT NVM device having Si₃N₄/HfO₂ as the CT layer can realize profound writing, erasing and retention performance, compared to the device having a single-layered trapping layer. In order to the characteristics of CT NVM device, this invention provides a charge-trap flash memory device having a low-high-low energy band structure as a trapping layer, in which the Si₃N₄/Al₂O₃/HfO₂ three-layered charge trapping layer is used as the trapping layer to form the low-high-low energy band structure. Most of electrons are trapped at the interface of Si₃N₄/HfO₂, so that embedding Al₂O₃ to the interface of Si₃N₄/Al₂O₃ can further improve the writing speed and retention characteristics of the CT NVM device. Such a device has short operating time, low voltage, long life cycle, and high number of cycles.

In summary, the present invention provides a charge-trap type flash memory device having a low-high-low energy band structure as a trapping layer, which can effectively improve the shortcomings of prior art. Embedding Al₂O₃ to the interface of Si₃N₄/HfO₂ can further improve the writing speed and retention characteristics of the CT NVM device. Such a device has short operating time, low voltage, long life cycle, and high number of cycles. This makes the invention more progressive and more practical in use which complies with the patent law.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

1. A charge-trap type flash memory device having a low-high-low energy band as a trapping layer, comprising
a silicon substrate,
a charge trapping (CT) layer, used to trap charges, wherein the charge trapping layer comprises a silicon nitride (Si₃N₄) film, an intermediate oxide layer and a hafnium oxide (HfO₂) film; the silicon nitride film contributes to improve the retention characteristics; the intermediate oxide layer is used to regulate the distribution of the trapped charges; the hafnium oxide film is used to increase the memory window; and the conduction band offset (ΔEc) of the intermediate oxide layer is greater than that of the silicon nitride film and the hafnium oxide film;
a tunneling oxide layer, between the silicon substrate and the charge trapping layer and adjacent the silicon nitride film to prevent any charges from losing from the charge trapping layer to the silicon substrate;
a metal gate electrode; and
a blocking oxide layer, disposed between the charge trapping layer and the metal gate electrode to block any charges so as to prevent any loss from the charge trapping layer to the metal gate electrode.

2. The charge-trap type flash memory device of claim 1, wherein the intermediate oxide layer is selected from silicon oxynitride (SiON), aluminum oxynitride (AlON) or aluminum oxide (Al₂O₃).

3. The charge-trap type flash memory device of claim 1, wherein the charge trapping layer is made of high dielectric constant (high-κ) material

4. The charge-trap type flash memory device of claim 1, wherein the tunneling oxide layer has a thickness of 2˜4 nanometers (nm).

5. The charge-trap type flash memory device of claim 1, wherein an equivalent silicon nitride thickness of the charge trapping layer comprising the silicon nitride film, an intermediate oxide layer and a hafnium oxide is 5˜7 nm.

6. The charge-trap type flash memory device of claim 5, wherein the silicon nitride film has a thickness of >3 nm.

7. The charge-trap type flash memory device of claim 5, wherein the intermediate oxide layer has a thickness of ≦3 nm.

8. The charge-trap type flash memory device of claim 1, wherein the blocking oxide layer has a thickness of 12˜18 nm.

9. The charge-trap type flash memory device of claim 1, wherein the metal gate electrode has a thickness of 40˜60 nm.

10. The charge-trap type flash memory device of claim 1, wherein the metal gate electrode is the one which is patterned by etching.
